(19) United States
(12) Patent Application Publication
(10) Pub. No.: US 2012/0133012 A1
(43) Pub. Date: May 31, 2012

(54) COMPOSITE SYSTEM FOR PHOTOVOLTAIC MODULES

(76) Inventors: Markus Rees, Eppstein (DE); Peter Waegli, Bremgarten (CH)

(21) Appl. No.: 13/382,542

(22) PCT Filed: Jul. 8, 2010
(86) PCT No.: PCT/EP2010/059788

§ 371 Date: Jan. 26, 2012

(30) Foreign Application Priority Data
Jul. 10, 2009 (DE) 10 2009 026 149.4

(51) Int. Cl. H01L 31/0232; H01L 31/18

(52) U.S. Cl. 257/432; 438/65; 257/E31.127

(57) ABSTRACT

The present invention relates to a composite system for photovoltaic (PV) modules. The composite system consists of a carrier foil, a metal foil applied onto the carrier foil, and an insulating layer applied onto the metal foil. Using different connecting techniques, different photovoltaic (PV) cells can be fastened to the composite system and electrically interconnected thereby. In addition, the invention relates to a method for producing the composite system for PV modules, and to the use of the composite system for the back side contacting of wafer cells that have both contacts on the same side and that are placed, with the contacts, onto conductor structures that interconnect them into a module, and to the use of the composite system for modules of internally interconnected thin-film cells.

The present invention relates to a composite system for photovoltaic (PV) modules. The composite system consists of a carrier foil, a metal foil applied onto the carrier foil, and an insulating layer applied onto the metal foil. Using different connecting techniques, different photovoltaic (PV) cells can be fastened to the composite system and electrically interconnected thereby.

In addition, the invention relates to a method for producing the composite system for PV modules, and to the use of the composite system for the back side contacting of wafer cells which have both contacts on the same side and which are placed, with the contacts, onto conductor structures that interconnect them into a module, and to the use of the composite system for modules of internally interconnected thin-film cells.

A PV module converts sunlight directly into electrical energy and contains a plurality of PV cells (up to 160 cells) as the most important component, these cells being interconnected. For this purpose, the cells are combined by means of different materials to form a composite which fulfils two purposes: the composite forms a transparent, radiation- and weather-resistant covering and provides robust electrical terminals by the corresponding packing. The brittle PV cells and electrical connections are protected against both mechanical influences and moisture. In addition, the packing of the PV cells allows sufficient cooling thereof. The electrical components are protected against access and the modules can be better handled and fixed. There is a wide range of designs of PV modules with different types of PV cells.

PV modules generally have a glass panel on the side facing the sun (front side), wherein a “safety glass insert” (SGI) is normally used. This is generally connected to the cells via a transparent plastics material layer, such as ethylene vinyl acetate (EVA) or silicone rubber. The PV cells are embedded in this plastics material layer and are electrically interconnected by small soldered strips. On the back side, the modules are terminated by a weatherproof plastics material composite foil, for example made of polyvinyl fluoride or polyester, or by a further glass pane. When manufacturing PV modules, these are generally laminated at approximately 150° C. During the lamination process, a clear, three-dimensionally cross-linked plastics material layer which can no longer melt, in which the PV cells are embedded and which is rigidly connected to the glass pane and to the back side foil is formed from the EVA foil, which is milky up to that point.

Monocrystalline and polycrystalline PV cells are produced from “wafers” (monocrystalline or polycrystalline silicon slices), as also used in identical or similar form for the production of semiconductors. Industrially, these silicon cells have an efficiency of up to 20% or more and a power density of 20 to 50 W/kg. A plurality of these cells are connected in series in a PV module by means of solder strips to form individual strands (“strings”) until the correct output voltage is reached. A plurality of such cell groups are then connected in parallel in order to add their output currents and to lead to the module terminals. The lines used for this purpose are called busbars. In order to string the cells together the front side of a cell (for example negative pole) must be connected to the back side of the next cell (positive pole) in each case, tin-plated copper strips often being used for this purpose.

Since it is costly and difficult to automate the connection of the front side of a cell to the back side of the respective neighboring cell, back side contacting is increasingly used. In particular, if increasingly thinner wafers are used for cost-saving reasons, these are more difficult to handle owing to the increased risk of breaking. In addition, the connection strips extending over the front side block out some of the light, which therefore cannot be used for power generation, and therefore the efficiency of the cells and of the entire module decreases. An approach to additionally reduce the optical losses caused by the strips required for stringing is described in US 2007/0125415 A1. In this case “light harvesting strings” are used, more precisely strips which reflect back the light which contacts the front side, that is to say which would be blocked out, at such an angle that it is reflected into the cell at the upper side of the covering glass. However, such strips are expensive since they have a silver surface and are difficult to connect to the cells without destroying the surface structure required for the reflection. In back side contacting the front contact is guided onto the back side by an appropriate design of the cell so that both contacts (+/−) are accessible on the same side. “Pick-and-place” techniques can thus be applied during module production, in which the cells can automatically be placed on the contact structure of a printed circuit board (PCB) and can be connected thereto by soldered, plug-in or adhesively bonded joints Such a PV module with back side contact is described, for example, in EP 1 449 261 [U.S. Pat. No. 7,217,883]. Contacting is still only provided on one side, which simplifies handling and simultaneously overcomes the problem of shadowing caused by the strips.

The printed circuit boards, which are arranged behind each cell, give the wafers additional stability, which is particularly advantageous in the case of thin wafers. However, such printed circuit boards are expensive and must in turn be interconnected, which either necessitates the connections of individual printed circuit boards or presupposes very large printed circuit boards (module scale), which are accordingly expensive to manufacture. In addition, these wafer cell modules consist of many different components which each have to be processed in individual processing steps, which is complex and cost intensive. The object of the present invention is therefore to overcome the above-described drawbacks of the prior art and to enable a simpler and more cost effective design of wafer cell modules, in particular with increasingly thinner wafer cells. However, with the use of increasingly thinner wafers it is to be assumed that some of the light is no longer absorbed in the wafer, but penetrates through it. It is therefore desirable to reflect this light back into the cell, where a further portion can be absorbed.

In contrast to monocrystalline and polycrystalline PV cells (wafer cells), “thin-film cells” usually consist of a thin semiconductor layer made of amorphous and/or microcrystalline silicon (a-Si or μ-Si), but also cadmium telluride (CdTe), copper indium diselenide (CIS) or other materials. The module efficiency of thin-film modules is between 5 and 7% owing to the reduced thickness of the silicon or semiconductor layer, and the power density is approximately 2000 W/kg. By means of the combination of amorphous and crystalline silicon, such as microcrystalline silicon, greater efficiencies of up to 10% can be achieved owing to improved utilization of the light spectrum. When producing thin-film modules the active semiconductor layer, typically amorphous and/or microcrystalline silicon, is applied using specific coating processes to a glass panel or to a flexible carrier, typically strips of steel or copper. An advantage in the production of modules using thin-film technology is the simple interconnection of the cells. After the coating with the active material, this is divided into cells using specific laser processes, these cells being strung together. External stringing using strips, as is used in wafer cell modules, is thus omitted. However, for current removal strips are also used for the “busbars” to carry off the current generated. Silicon thin-film PV cells are described for example in DE 44 10 220 [U.S. Pat. No. 5,853,498] and in DE 10 2006 044 545.

The most commonly used thin-film cell module types consist of an (anti-reflection-coated) glass panel, on which an electrically conductive and optically transparent layer is applied (transparent conductive oxide—TCO, usually zinc oxide). This layer forms the front contact and is structured by laser to achieve the partitioning into cells. An active layer, for example silicon, is applied to this, followed by the back side contact and a reflector since the light has to be guided a number of times through the thin active layer (1 to 2 μm) in order to be sufficiently absorbed. Behind, the module is terminated and protected against environmental influences. The back side reflector may consist of a metal coating, of which the raw texture enables diffuse reflection and simultaneously acts as a conductor which is responsible for the stringing of the cells (integrated back contact and reflector); or the reflector is applied in the form of white paint which reflects diffusely. In this case, between the active layer and the white paint, an optically transparent conductor, generally TCO is necessary for the stringing.

A drawback in thin-film modules with an integrated back contact and reflector is that the properties of the reflector and contact cannot be optimized separately. For example, if the texture of the corresponding layer is increased, the diffuse reflection properties will improve, but at the same time the electrical resistance will increase. Furthermore, the texture may only be controlled to a limited extent by adjusting the coating processes. In addition, the metal layer has a disruptive effect on the laser process via which the module is divided into cells. Uncontrolled spatters of metal may trigger short circuits, which could destroy parts of the module. The plastics materials used to seal off the module are expensive and difficult to process. Thin-film modules having a separate reflector and back contact are therefore easier to produce. The paint used as a reflector is associated with drawbacks, however, since the reflection values to be achieved are unsatisfactory over a broader wavelength range. This is disadvantageous if cells/modules are to be produced which consist of a plurality of active layers and together cover a broader wavelength range in order to increase the overall efficiency of the module.

In both variants of thin-film modules busbars in the form of strips have to be applied on either side in the longitudinal direction of the module. Owing to the length of the strips and the inherent curvature thereof, this is complex and expensive. The construction of the strips from tin-coated copper emerges as a further drawback. If the tin layer is damaged or missing completely, corrosion may start from the exposed copper surface and reduces the service life of the module. On the whole, the modules consist of many components which have to be processed in a number of processing steps, which is cost intensive, complex and susceptible to errors. The object of the present invention is therefore to additionally allow a simpler and more cost effective construction of thin-film modules.

The object is achieved by the composite system according to the invention, the method for producing such a composite system and the use thereof for different PV modules. This composite system performs a number of functions which are necessary for the interconnection and linking of photovoltaic cells and photovoltaic modules as well as for the termination of the modules and the protection thereof against environmental influences. In this case unabsorbed radiation in the cells is reflected back into the cells so that it can be recycled. The composite system according to the invention thus allows a simple and cost effective production of photovoltaic modules and an improvement of efficiency and reliability. The proposed composite system is thus suitable both for back contacting of wafer cell modules and for thin-film cell modules. The design, structuring and contacting of the conductor ultimately determines the application for which the composite system will be used.

The composite system for photovoltaic applications consists of a carrier foil, with the aid of which the module is sealed against environmental influences and which carries the further functional layers. A metal foil is applied to the carrier foil and is structured accordingly to string the cells and is used as a busbar (electrical function) and simultaneously performs an optical function in which it acts as a reflector. The metal foil is designed in such a way that it is provided with a surface texture. An insulating layer is applied adhesively to the metal foil and insulates the cell electrically from the metal foil. This layer is removed at the contact points. This may occur by mechanical corrosion or by corrosion using lasers. The insulating layer is also provided with a connection means. This facilitates the fixing of cells on the foil composite. The light which penetrates through the active layer is allowed to pass through to the metal foil and is therefore reflected back into the active layer.

The composite system can be connected in a stable manner to the PV cells using different connecting techniques. In an advantageous embodiment of the composite system according to the invention, the system is connected to the cells using an electrically conductive adhesive. In an alternative embodiment this connection is produced mechanically by pressing or by laser machining.

Alternatively, it is also possible to simultaneously produce electrical connections by soldering during the lamination operation, preferably using a solder having a low meting point.

The connection means on the insulating layer may be an adhesive. Alternatively, it is also possible for the insulating layer to be self-adhesive. This affords the advantage that the cells can be handled in a much simpler manner. It is thus possible to fix the photovoltaic cells, which are already adhesive, to the foil composite before they reach the laminator. The cells are then ultimately connected to the foil composite by the lamination process.

The carrier foil preferably consists of polyvinyl butyral (PVB), polyvinyl fluoride, ethylene vinyl acetate (EVA) or a plastics material having comparable thermal and physical properties.

In an alternative embodiment the carrier foil preferably consists of polyethylene terephthalate in the form of biaxially oriented polyester (boPET) or of composites of different materials. The composite system is thus provided with additional mechanical stability.

Alternatively, a layer thickness of 25 μm to 100 μm, more preferably 40 μm to 80 μm may also be used to improve conductivity and to reduce resistance losses in the module.

In a further advantageous embodiment the carrier foil is coated on the back side, preferably with aluminum. This is particularly advantageous if the carrier foil forms the module termination.

The metal foil, which is applied adhesively to the carrier foil, preferably consists of tin or a tin alloy, or a plated tin foil. It is also possible to use copper, aluminum or silver for this purpose. In a further advantageous embodiment the metal foil is at least 5 μm thick, preferably 5 to 25 μm thick, and more preferably 10 to 20 μm thick.

In a further advantageous embodiment of the present invention the metal foil is provided with a layer which increases reflection. This is preferably a tin foil coated with a silver surface or aluminum coated with silicon dioxide and/or titanium dioxide. This layer enables a particularly efficient reflection of the light which penetrates through the active layer. This layer should have a reflection of >80% in the wavelength range of 300 nm to 1000 nm.

In a further advantageous embodiment the metal foil is provided with a surface texture. This ensures that the light is reflected back in such a way that the most effective “light trapping” possible is achieved. The surface texture preferably consists of three-dimensional, regular or irregular structures. The surface texture of the metal foil particularly preferably consists of pyramids or hemispheres. In this case it is advantageous if the surface texture and/or the pyramids or hemispheres are 1 to 20 μm tall, preferably 5 to 15 μm tall, more preferably 5 to 10 μm tall. It is further advantageous if the surface texture and/or the pyramids or hemispheres have a random height distribution of 1 to 20 μm, preferably 5 to 15 μm, more preferably 5 to 10 μm. In a further advantageous embodiment the surface texture consists of pyramids of the preferred size and with a vertical angle of <160°, preferably <140°.

In a further alternative embodiment the surface texture of the metal foil consists of pyramids or hemispheres which have a characteristic size of 1000 nm at most. It is further preferred if the surface texture and/or the pyramids or hemispheres have a random height distribution of 10 to 1000 nm, preferably 100 to 1000 nm.

In a further advantageous embodiment of the present invention the insulating layer, which is applied adhesively to the metal foil, consists of an optically transparent and electrically insulating material. It is preferably a suitable plastics material or a synthetic resin. The synthetic resin may preferably be an epoxy resin. This layer may optionally also be applied to the metal foil using a physical gas separation (PVD) method or using a sol-gel method. This layer is to insulate the metal layer electrically from the cell and should have a specific dielectric strength. Additionally however, this layer should also be optically transparent in a range of 400 nm to 1000 nm (absorption coefficient α<3*10⁻³/cm). In addition, the insulating layer should have a refractive index in the above-described wavelength range which is greater than the refractive index of the glass used as the entry window. The refractive index in this range is preferably >1.4, more preferably >1.6. The insulating layer is interrupted at the contacting points so that electrical contacts between the metal layer within the composite system and the PV cells can be produced.

In an alternative embodiment the insulating layer has a refractive index which is less than or equal to the refractive index of the glass used as the entry window. This embodiment may preferably be provided if the contribution of the composite foil to light trapping is not crucial. The suitable plastics material which is used for the insulating layer is preferably PVB. This material has the advantage that the foil is simultaneously adhered to the cells during the lamination process or the prior assembly process of the cell. The latter may be particularly advantageous since the transport of the assembled and installed module into the laminator is simplified and any shifting of components during the lamination process is prevented. For this purpose, the foil system may be heated during the assembly process of the cells (pick-and-place) so that the PVB is sticky and fixes the cells.

The method for producing a composite system for PV modules includes the following method steps: a preferably textured metal foil is joined to a carrier foil by an adhesive bond. The metal foil is then corroded locally, for example by means of a laser process, and is thus structured in such a way that the conductor structure required for the busbars and/or the stringing is produced. These joined layers are then connected to the insulating layer; and the insulating layer is opened at specific points in order to produce the electrical contacts. For reasons of surface protection, it may be preferable not to form the contact openings until just before the lamination operation. Depending on the structuring of the metal foil, the composite system is suitable for the production of wafer cells or thin-film cells. The individual foils are preferably connected by lamination or by the adhesive properties of the foil itself. Alternatively, it is also possible to first connect the metal foil to the insulating layer and then to connect these layers to the carrier foil.

Lastly, a connection means may be applied to the contacting openings. The connection means is preferably a thermally curing, electrically conductive adhesive so that the electrical connections to the PV cells can be produced during the lamination process. Alternatively, the composite system and wafer cells or thin-film cells may be electrically connected by a laser soldering process. In this case, however, an additional processing step is necessary. A further alternative of the electrical connection is the mechanical pressing of the composite system with the contacting openings.

Should the composite system be used for the back side contacting of wafer cell modules, this leads to a large cost reduction, since expensive conductor plates do not have to be used. In addition, the reflectors are integrated directly into the conductor structure, which allows the use of thinner wafers.

In a further advantageous embodiment of the method according to the invention for producing a composite system for PV modules, the desired reflector texture is stamped into the metal foil before the carrier foil and metal foil are connected. In an alternative advantageous embodiment the reflector texture is stamped into the carrier foil connected to the metal foil, or is transferred onto the metal foil from a stamped insulating layer during the connection operation. This texture ensures that the light is reflected back in such a way that as much light as possible is guided back into the PV cells, where it is absorbed (light trapping).

In a further alternative embodiment the metal layer may be perforated so that an improved adhesion to the adjacent layers can be produced.

In a further advantageous embodiment polyvinyl butyral (PVB), which is used in the production of composite glasses and with which there is much practical experience, is preferably used as the carrier foil. In addition, PVB is already currently used in modules, and therefore the process adjustments for the module producer necessary for the use of the composite system are less drastic.

A synthetic resin, particularly preferably an epoxy resin, is preferably used as a material for the insulating layer. For example, if the texture were stamped into the metal foil this can then be filled and stabilized with epoxy resin. This epoxy resin must not become soft again during the lamination process so that the texture remains. The epoxy resin can be cured by heat and/or UV radiation. In addition however, this layer is also not to be optically transparent in a range of 300 nm to 1000 nm (α<3*10⁻³/cm) and should have a refractive index greater than the refractive index of the front glass intended for use. The refractive index in this range is preferably >1.4, more preferably >1.6. The insulating layer has interruptions at the contacting points between the metal foil in the composite system and the PV cells.

In a preferred embodiment of the invention the insulating layer is applied in the form of a coating to the metal foil. This may occur by PVD or sol-gel processes for example. Advantages of these types of coating are optimized properties and low, defined layer thicknesses.

In a further advantageous embodiment of the method according to the invention the metal foil is coated in the transport direction during the connection operation. This may preferably take place by means of a laser process. The composite system can thus already be produced in the desired shape and size.

The composite system thus produced may be connected to the PV cells in a process, for example lamination or pressing, so that the cells are strung to form a module (stringing). In addition, a connection to the outside is produced via the carrier foil and the module is terminated in such a way that it is protected against environmental influences.

In an alternative embodiment of the method according to the invention electrical connections are additionally produced between the composite system and the PV cells during the lamination process in a single method step, preferably by means of soldering, more preferably using solder having a low meting point; the module is sealed toward the rear; a covering glass is applied and/or the PV cells are embedded.

The object of the invention is also to use the composite system according to the invention for back side contacting of wafer cell modules. Wafer cells in which both contacts are arranged on one side are placed, with these contacts, onto the conductor structures and are connected thereto. The connection may take place during the lamination operation, in which the electrical cell connections are produced at the same time in this method step. A plurality of wafer cells can thus be connected to form individual strands and ultimately connected by busbars to form a larger unit in a wafer cell module. During the lamination process, the contact between the cells and the corresponding conductor structure cut into the metal foil is produced by purely mechanical contacting, by pressing or by the curing of an electrically conductive adhesive.

Alternatively, it is also possible to produce electrical connections by soldering at the same time during the lamination operation, preferably using a solder having a low melting point.

On the other hand, the invention relates to the use of the described composite system for the production of thin-film cell modules. For this purpose, the insulating layer is opened along the longitudinal sides of the module edges for the contacting of the metal foil. This must contact the active layer in segments or over the entire length of the module at the module edges. The metal foil is divided into two parts along the longitudinal side so that a conductor structure is produced which also serves as busbars. These two reflector strips are electrically insulated from the active layer by the insulating layer on the surface. Owing to the lack of an insulating layer at the edges of the thin-film cell module, the carrier foil must compensate for this difference in thickness. It is thus ensured that the module coverings can be rigidly connected to the composite system and that no moisture penetrates the module.

In a further advantageous embodiment of the use of the composite system according to the invention for back side contacting of wafer cell modules or for the production of thin-film cell modules, the carrier foil forms the back side module termination as protection against environmental influences. Alternatively, it is possible for the carrier foil to enter into a mechanically rigid connection to a back-side module covering, which for example may consist of a glass panel or of a further additional plastics material foil.

Owing to the use of the composite system according to the invention, there are a number of advantages over the prior art. On the one hand, the material costs are reduced. The strips for the busbars and for the stringing inside the wafer cell modules are omitted. In addition, no reflector paint is used in the case of the thin-film modules. Expensive conductor plates do not have to be used and, on the whole, fewer components are processed. On the other hand, the number of processing steps during module production is reduced. The production of the electrical cell connections and the contacting and sealing of the module may be carried out in a single processing step. The complex assembly of the strips is omitted and the wafer cells provided for back side contacting can be fitted directly by pick-and-place processes, since all electrical connections are arranged in a single plane. A further advantage emerges from the fact that the composite system, depending on the structuring and contacting of the conductor, can be used both for wafer cells and for thin-film cells. This also brings further advantages for system and module producers, since both types of modules are produced and therefore many processes can be unified. Lastly, the produced PV modules have a range of improved properties. Owing to the use of the conductors as reflectors in wafer cell modules or improved reflection within the thin-film modules, efficiency is increased. The service life of the modules is increased since copper no longer has to be used. Since the modules are formed of fewer components, better reliability and lower costs are achieved on the whole.

A further advantage is the achievable increase in efficiency which is provided by the recycling of unused radiation and by the reduction in resistance losses owing to an appropriate design of the metal layer (material and cross-section).

The invention will be described hereinafter in greater detail on the basis of drawings, the invention naturally not being limited to the embodiments illustrated in the drawings, in which:

FIG. 1 is a schematic cross-sectional view through the composite system according to the invention for photovoltaic applications;

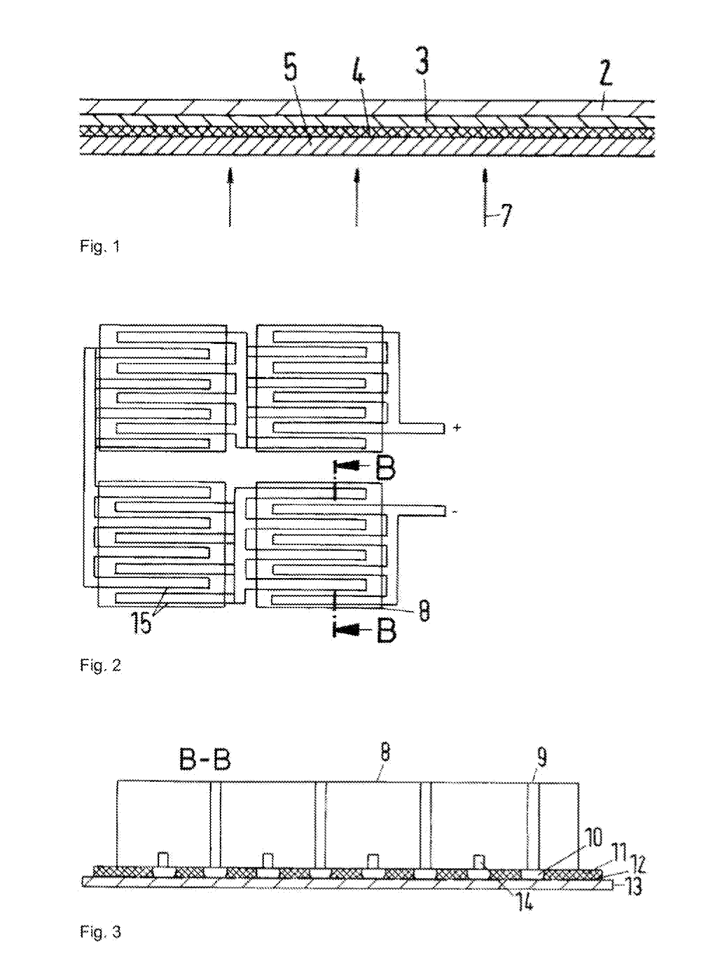

FIG. 2 is a schematic representation of a possible embodiment of cell interconnection in wafer cell modules;

FIG. 3 is a schematic cross-sectional view through the composite system according to the invention for back side contacting of wafer cell modules;

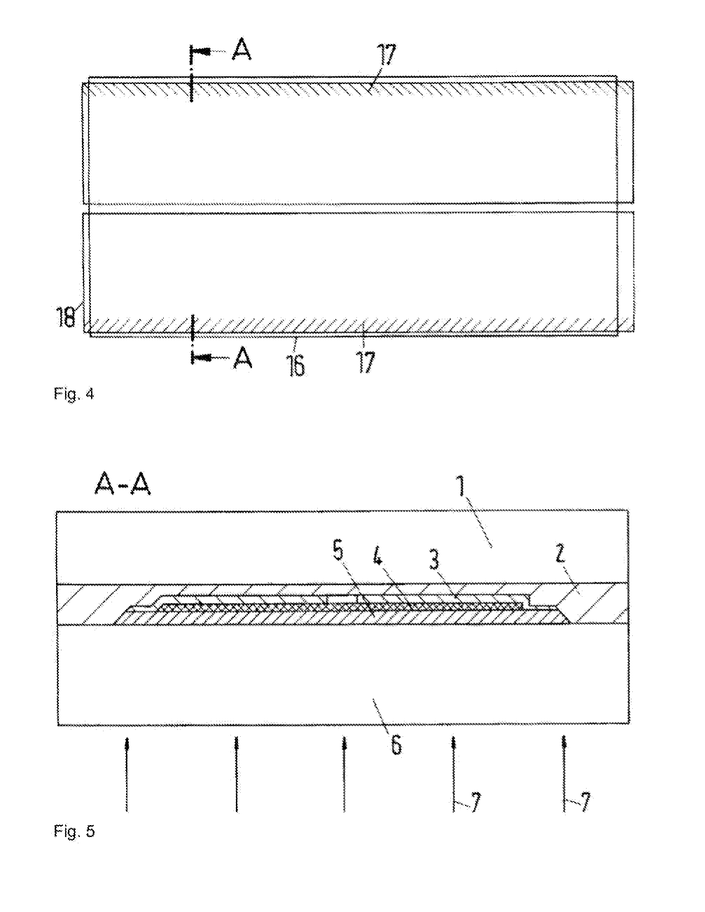

FIG. 4 is an overview of a composite system for thin-film modules of the “separate reflector and back contact” type; and

FIG. 5 is a schematic cross-sectional view through a possible layer structure of the composite system according to the invention for thin-film modules.

FIG. 1 shows a schematic cross-section through the composite system according to the invention for photovoltaic applications. A “carrier foil” 2, for example made of polyvinyl butyral (PVB) carries the further functional layers and produces the connection for sealing the module against environmental influences. A metal foil 3 is applied adhesively to this layer and, for example, is produced from tin, is more than 5 μm thick and has a conductor structure (FIG. 2). This layer strings the cells together and is used as a busbar, but also acts as a reflector. An insulating layer 4 is applied to this metal foil and insulates the metal foil 3 from the cell. With the aid of an adhesive for example, the active layer 5 such as a wafer cell or thin-film cell is connected to the insulating layer 4. The insulating layer 4 must have interruptions at the points at which the electrical contacts are to be produced (not shown in this figure). The light 7 hits the active layer 5 and the part of the light which penetrates through the active layer 5 is reflected back by the metal foil 3 so as to be guided back into the active layer 5.

FIG. 2 shows a schematic view of a possible embodiment of cell interconnection (stringing) 15 in wafer cell modules. The conductors are cut from the metal foil and are provided, for example, with an electrically conductive adhesive. The wafer cells 8, in which both contacts (+/−) are located on the same side, are placed onto these conductors and are connected to the composite system according to the invention during the lamination operation. The stringing 15 of the wafer cells 8 with the composite system is thus produced and the module is outwardly terminated.

FIG. 3 shows a schematic cross-section through the composite system according to the invention for back side contacting of wafer cell modules. Both the front contacts 9 and the back contacts 14 are located on the underside of the wafer cells 8. An electrical connection 10 can thus be produced, for example via a conductive adhesive. The insulating layer 11 is interrupted at the contact points so that the contacts of the wafer cells 9, 14 can form a connection to the reflecting conductors 12, which are applied to the carrier foil 13. If the light penetrates through the wafer cell 8, it is reflected at the conductors 12 so that it passes back into the wafer cell so as to allow greater energy efficiency.

FIG. 4 shows an overview of a composite system for thin-film modules of the “separate reflector and back contact” type. The metal foil is divided into two parts longitudinally along the center of the module, these two parts acting as busbars and additionally forming a textured reflector 18. These two reflector strips are electrically insulated from the active layer, in this case a thin-film cell with internal stringing 16, by the insulating layer on the surface. The insulating layer is removed at the edges of the active layer so that the module can be contacted here 17 for current removal. The reflector layers thus act as busbars.

As illustrated in cross-section in FIG. 5, the carrier foil 2 must compensate for the difference in thickness caused by the lack of an insulating layer 4 at the module edges. The composite system can this be rigidly connected to the two glass panels, which form the front side 6 and back side 1 of the module. This ensures that no moisture can penetrate the module. The light 7 thus penetrates through the front glass 6 and the active layer 5 and is then reflected at the metal foil 3 (diffusely) and passes back into the active layer to allow greater energy efficiency.

### LIST OF REFERENCE NUMERALS

1 back side carrier
2 carrier foil
3 metal foil
4 optical transparent insulating layer
5 active layer
6 front glass
7 incident light
8 wafer cell
9 front contact
10 electrical connection
11 insulating layer
12 conductors
13 carrier foil
14 back contact
15 stringing
16 thin-film cell with internal stringing
17 busbar/reflector connection to the cell
18 textured reflector

1-12. (canceled)

13. A composite system for photovoltaic application, except for as a coating of electrical household appliances, the system consisting of:
a carrier foil;
a metal foil applied onto the carrier foil and provided with a surface texture; and
an insulating layer applied onto the metal foil and provided with connection means.

14. The composite system according to claim 13, wherein the connection means on the insulating layer
is an adhesive; and/or
the insulating layer is adhesive.

15. The composite system according to claim 13, wherein the insulating layer
consists of a transparent and electrically insulating plastic or a sol-gel layer or a dielectric layer, or
has a refractive index of >1.6 in the wavelength range of 400 nm to 1000 nm, or
has a refractive index that is less than or equal to the refractive index of the glass used as the entry window, or
consists of a plastics material which has adhesive properties.

16. The composite system according to claim 13, wherein the carrier foil
consists of polyvinyl butyral, polyvinyl fluoride, ethylene vinyl acetate or a plastics material having comparable thermal and physical properties, or
consists of polyethylene terephthalate in the form of biaxially oriented polyester or
is formed as a composite with different materials, or
is coated on the back side with aluminum.

17. The composite system according to claim 13, wherein the metal foil
consists of copper, aluminum, silver, or a tin alloy or a plated tin foil; or
is more than 5 μm thick; or
is provided with a layer of silicon dioxide or titanium dioxide that increases reflection, the layer on the metal foil having a reflectivity of >80% in the wavelength range of 300 nm to 1000 nm; or
is provided with a surface texture that consists of three-dimensional, regular or irregular pyramids or hemispheres, the texture preferably having a random height distribution of 5 μm to 10 μm or consisting of pyramids having a vertical angle of <140°; or
is provided with a surface texture consisting of three-dimensional regular or irregular pyramids or hemispheres, the texture being 1000 nm tall at most, the surface texture or the pyramids or hemispheres having a random height distribution of 10 to 1000 nm.

18. A method for producing a composite system according to claim 13 for PV modules, the method including the following steps:
producing a metal foil;
connecting a metal foil to a carrier foil by an adhesive connection;
connecting the metal foil and carrier foil to an insulating layer by an adhesive connection; and
opening the insulating layer for contacting.

19. A method for producing a composite system for PV modules, the method including the following steps:
producing a metal foil;
connecting a metal foil to an insulating layer by an adhesive connection;
connecting the metal foil and insulating layer to a carrier foil by an adhesive connection; and
opening the insulating layer for contacting the metal foil.

20. The method according to either claim 19, wherein
during or after the connection of the metal foil and the carrier foil, a conductor structure is cut into the metal foil by a laser; or
before or after the connection of the carrier foil to the metal foil, a reflector texture is stamped into the metal foil; or
the insulating layer has a reflector texture on the side facing the metal foil which is transferred to the metal foil during to the connection operation; or
the metal foil is perforated; or
the metal foil is cut in the transport direction during connection to the carrier foil by a laser; or
the carrier foil consists of polyvinyl butyral; or
a synthetic resin is used as the insulating layer and is cured by heat or UV radiation; or
the insulating layer consists of a dielectric layer that is applied by a PVD method; or
an electrical connection between the composite system and the PV cells is produced by using a thermally curing electrically conductive adhesive on the contacting openings or by a laser soldering process; or
the composite system is connected to PV cells by lamination or pressing so that the PV cells are interconnected to form a module.

21. The method according to claim 20, further comprising during the lamination process in a single step:
producing electrical connections between the composite system and the PV cells by soldering solder having a low meting point;
sealing the module toward the rear;
applying a covering glass to the module; or
embedding the PV cells.

22. A use of a composite system claim 13 for back side contacting of wafer cell modules, wherein
a wafer cell which has both contacts on the same side is placed, with these contacts, onto the conductor structure and is connected thereto; or
the cell adheres to the insulating layer during the assembly process and is thus fixed; or
the carrier foil forms the back side module termination as protection against environmental influences; or
the carrier foil forms a mechanical rigid connection to a back side module covering.

23. A use of a composite system according to claim 13 for the production of busbars in thin-film cell modules, wherein
the insulating layer is opened along the longitudinal sides of the module edges for the contacting of the metal foil;
the metal foil is divided into two parts along the longitudinal side and a conductor structure is thus formed which serves as busbars;
the metal foil also acts as a reflector.

24. The use of a composite system according to claim 23, wherein
the carrier foil compensates for a difference in thickness at the module edges caused by the lack of an insulating layer at the module edges of the thin-film cell module; or
the metal foil contacts the active layer in segments or over the entire length of the module at the module edges; or
the carrier foil forms the back side module termination as protection against environmental influences and forms a mechanical rigid connection to a back side module covering.
